(19) United States
(12) Patent Application Publication
(10) Pub. No.: US 2026/0247977 A1
(43) Pub. Date: Aug. 20, 2026

(54) SEMICONDUCTOR DEVICES WITH POLYIMIDE FILLED CRACK-STOP STRUCTURES AND METHODS FOR MAKING THE SAME

(71) Applicant: Micron Technology, Inc., Boise, ID (US)

(72) Inventors: Yichen Wang, Taichung (TW); Min-Ci Wu, Taichung (TW); Tsung Che Tsai, Tainan City (TW); Che Sheng Kung, Taichung (TW)

(21) Appl. No.: 19/464,443

(22) Filed: Jan. 29, 2026

Related U.S. Application Data
(60) Provisional application No. 63/760,511, filed on Feb. 19, 2025.

(51) Int. Cl. H10W 42/00; H10W 74/01; H10W 74/10; H10W 74/43; H10W 74/47

(52) U.S. Cl. CPC H10W 42/121; H10W 74/01; H10W 74/147; H10W 74/43; H10W 74/47

(57) ABSTRACT

A semiconductor device is provided. The device includes a substrate including an upper surface, an oxide layer disposed over the upper surface of the substrate, and a crack-stop structure extending into an opening in the oxide layer. The crack-stop structure comprises a metal material that lines lower and sidewall surfaces of the opening and that overlaps a top surface of the oxide layer adjacent the opening. The device further includes a polyimide fill disposed in a cavity of the crack-stop structure and extending below the top surface of the oxide layer.

### CROSS-REFERENCE TO RELATED APPLICATION(S)

The present application claims priority to U.S. Provisional Patent Application No. 63/760,511, filed February 19, 2025, the disclosure of which is incorporated herein by reference in its entirety.

### TECHNICAL FIELD

The present disclosure generally relates to semiconductor device assemblies, and more particularly relates to semiconductor devices with polyimide filled crack-stop structures and methods for making the same.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are "packaged" to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIGS. 1 and 2 are simplified schematic cross-sectional views of example semiconductor devices with crack-stop structures.

FIGS. 2 is a simplified schematic cross-sectional view of a semiconductor device assembly in accordance with embodiments of the present technology.

FIGS. 3 through 6 are a simplified schematic cross-sectional illustrating a series of fabrication steps of semiconductor devices with crack-stop structures in accordance with an embodiment of the present technology.

FIGS. 7 through 10 are simplified schematic cross-sectional and partial cross-sectional views of semiconductor devices with crack-stop structures in accordance with embodiments of the present technology.

FIGS. 11 and 12 are simplified schematic plan views of semiconductor devices with crack-stop structures in accordance with embodiments of the present technology.

FIG. 13 is a flow chart illustrating a method of making a semiconductor device in accordance with an embodiment of the present technology.

FIG. 14 is a schematic view showing a system that includes a semiconductor device configured in accordance with an embodiment of the present technology.

### DETAILED DESCRIPTION

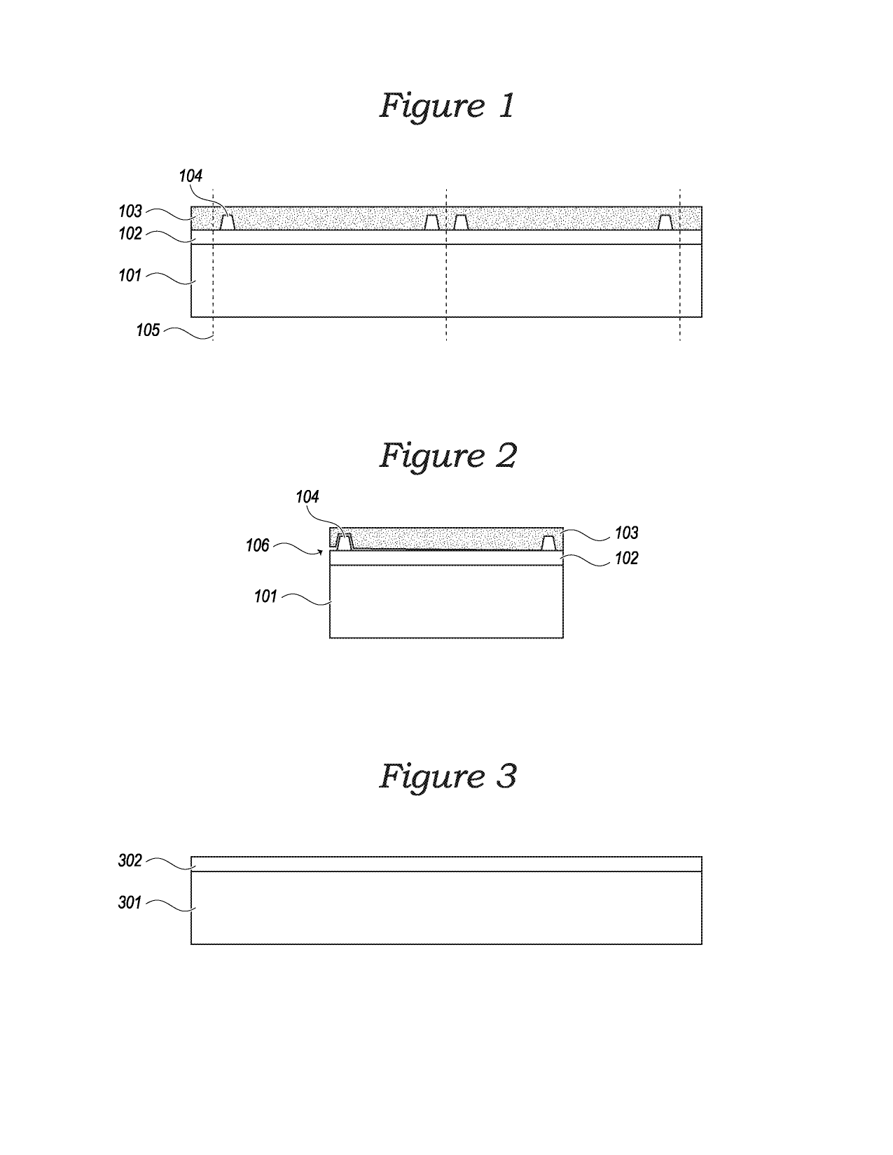

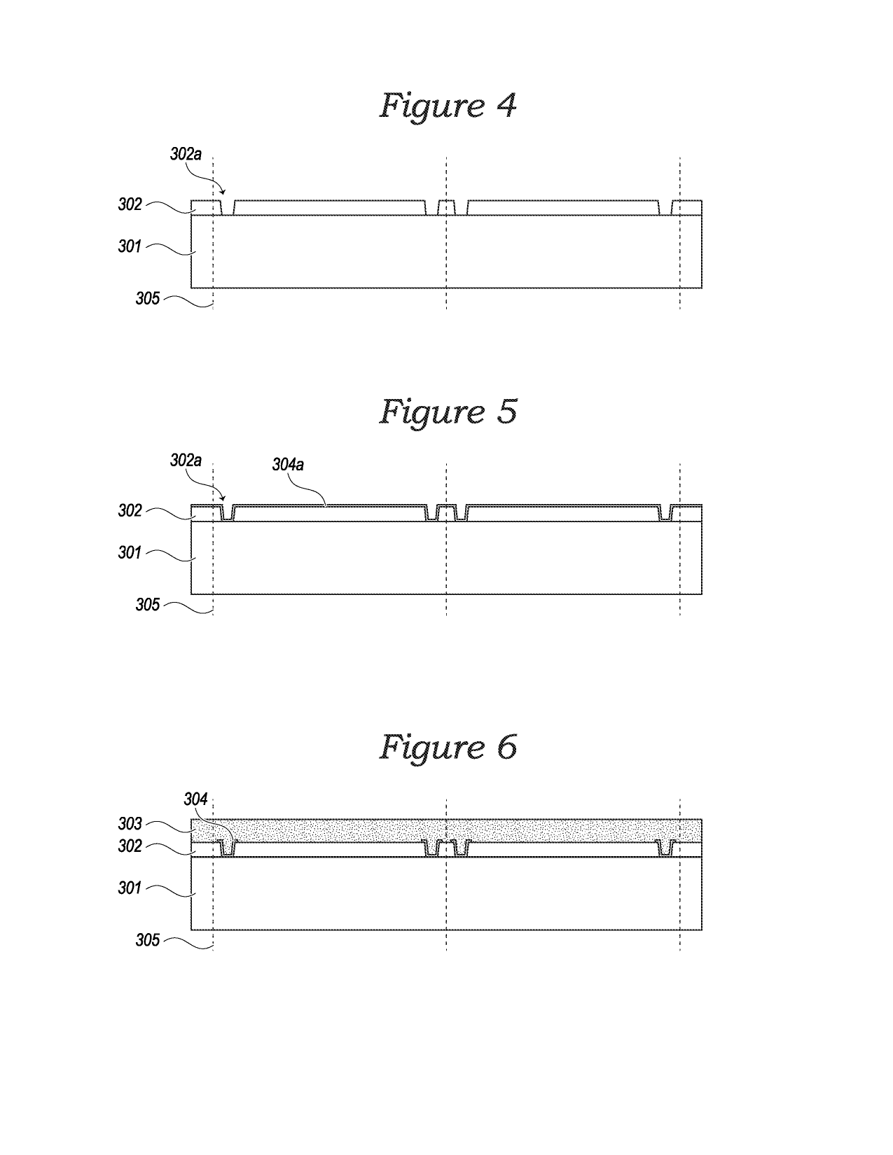

Some packaged semiconductor devices include a layer of polyimide material between an oxide surface (e.g., a silicon oxide passivation layer) that covers a layer of active semiconductor devices and a layer of encapsulant material (e.g., resinous mold material) that provides environmental and mechanical protection to the device. The interface between the polyimide material and the oxide layer can, following the singulation of the device from a wafer (or panel or strip) in which it was fabricated can present an opportunity for mechanical damage—namely, a lateral crack can propagate from the singulated edge of the device along the interface between the polyimide and the oxide, threatening the integrity and functionality of the device. To address this issue, some semiconductor devices can incorporate one or more crack-stop structures located proximate to the singulated edge of the device, to interrupt the propagation of such a crack before it extends into sensitive areas of the device (e.g., above or near the active circuitry or interconnect structures that may be formed in a metallization layer in or adjacent the oxide layer). Such devices are illustrated by way of example in FIGS. 1 and 2.

As can be seen with reference to FIG. 1, a semiconductor wafer 101 can include an oxide layer 102 (e.g., a BEOL metallization layer or an oxide layer disposed thereupon) over which is disposed a layer 103 of polyimide. To interrupt the propagation of cracks between the oxide layer 102 and the layer 103 of polyimide that may be formed at scribe lines 105 along which individual devices are singulated, crack-stop structures 104 may be disposed proximate to the scribe lines 105. The crack-stop structures may be metal structures (e.g., aluminum, copper, silver, gold, tungsten, alloys thereof, etc.) formed over the oxide layer to provide increased surface area to which the layer 103 of polyimide can adhere. As can be seen with reference to FIG. 2, a lateral crack 106 that may be initiated by the singulation of a device can be interrupted by the crack-stop structure 104 before reaching medial regions of the device in which interconnects or other circuitry (not illustrated) are located.

A challenge of designing a crack-stop structure is to provide sufficient surface area for the interface of the crack-stop structure and the polyimide layer to prevent propagation past the crack-stop structure, and also to provide sufficient adhesion between the crack-stop structure and the oxide layer to prevent the propagation of the crack between the crack-stop structure and the oxide layer. To address these challenges and others, various embodiments of the present application provide semiconductor devices in which crack-stop structures are provided with geometries that increase the area of both the polyimide layer and the oxide layer with the crack-stop structure.

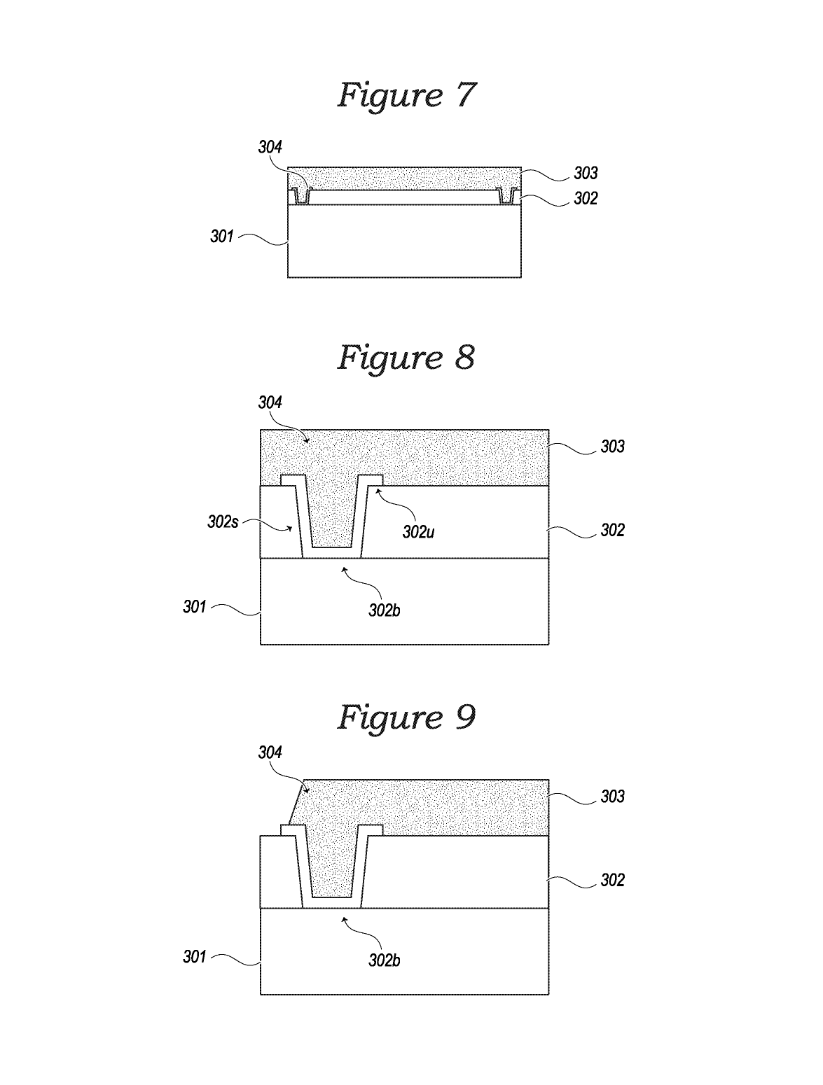

FIGS. 3 through 6 are simplified schematic cross-sectional views illustrating a series of fabrication steps of semiconductor devices having crack-stop structures in accordance with an embodiment of the present technology. Beginning with FIG. 3, a substrate 301 (e.g., in wafer-level, panel-level, strip-level, or in some embodiments, pre-singulated) is provided. An oxide layer 102 is disposed over the substrate (e.g., as part of a back-end of line (BEOL) metallization and interconnect formation step, or subsequent to such a step and over other BEOL metallization and oxide layers). As illustrated in FIG. 4, openings 302a are formed in the oxide layer adjacent to scribe lines 305 along which individual devices will later be singulated. The openings may be formed by etching (e.g., through photoresist masks with corresponding openings, or through other maskless etching approaches). Following the formation of openings 302a, as illustrated in FIG. 5, a metal material 304a may be plated or otherwise disposed over the surface of the oxide layer 302 and into the openings 302a, such that the material lines bottom and sidewall surfaces of the openings 302a in addition to the upper surface of the oxide material 302. The metal material 304a may be aluminum or another metal material compatible with BEOL processing (e.g., copper, gold, silver, tungsten, alloys thereof, etc.).

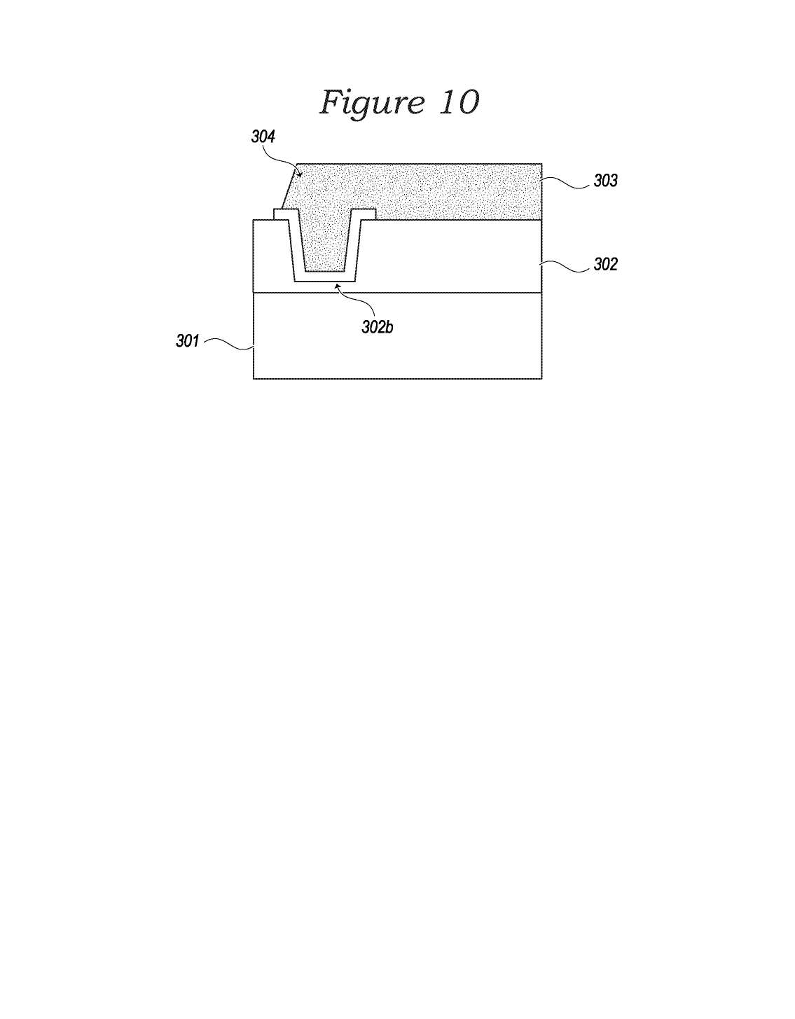

Following the formation of the metal material 304a, crack-stop structures 304 can be formed by etching away or otherwise removing portions of the metal material 304a to leave metal crack-stop structure 304 in the openings 302a of the oxide material 302. The remaining metal material of crack-stop structure 304 lines the bottom and sidewall surfaces of the openings 302a in addition to portions of the upper surface of the oxide material 302 that are adjacent the openings 302a. Subsequently, a layer 303 of polyimide is disposed over and into the crack-stop structures 304 and the upper surface of the oxide layer 302, as shown in FIG. 6. Although omitted from the illustration for simplicity’s sake, a subsequent layer of encapsulating mold material may be formed over the polyimide prior to singulation. The mold material may contact only the layer 303 of polyimide in some embodiments, although in others the polyimide material may not completely cover the oxide layer 302 (e.g., the layer 303 of polyimide may be patterned to expose portions of the oxide layer, as is illustrated below in greater detail with respect to FIGS. 9 and 10). In a subsequent step individual devices may be singulated along scribe lines 305 (e.g., via mechanical sawing, laser etching, stealth dicing, etc.), resulting in multiple singulated semiconductor devices, such as the device illustrated in FIG. 7.

Greater detail of various embodiments of the crack-stop structure 304 are illustrated in partial schematic cross-sectional views in FIGS. 8–10. As can be seen in the embodiment illustrated in FIG. 8, the depth of the opening in the oxide layer 302 may be equal to the thickness of the oxide layer 302, such that the bottom surface 302b of the opening is defined by a lower structure (e.g., substrate 301, or a lower metallization layer or layer of oxide material). The metal of the crack-stop structure 304 lines the bottom surface 302b, sidewall surfaces 302s, and a portion of the upper surface 302u of the oxide layer 302 adjacent the opening. The thickness of the metal material may between about 1 and 6 µm, and may be consistently thick in regions 302b, 302s, and 302u, or may vary from region to region (e.g., according to the nature of the deposition of the metal material – if deposited via anisotropic deposition, the sidewall regions may only be between 0.5 and 3 µm thick). The lateral overlap of the metal material and the upper surface 302u adjacent the opening may vary between 0.5 and 6 µm.

Furthermore, as illustrated in FIG. 9, in some embodiments the layer 303 of polyimide may be patterned (following the deposition illustrated in FIG. 6, above) to expose portions of the oxide layer 302, such as the portions of the oxide layer 302 that lie between the crack-stop structure 304 and the scribe line 305 to which it is proximate, resulting in a polyimide layer with a sloped edge intersecting the portion of the crack-stop structure 304 that overlaps the upper surface 302u of the oxide layer 302 adjacent the lateral edge of the singulated semiconductor device (e.g., such that the subsequently disposed encapsulant material directly interfaces the oxide layer 302 at the edge of the semiconductor device)

In yet another embodiment, illustrated in FIG. 10, the depth of the opening in the oxide layer 302 may be less than the thickness of the oxide layer 302, such that the bottom surface 302b of the opening defined by a remaining portion of the oxide layer 302 not removed in the etching process illustrated in FIG. 4. In such an embodiment, the opening may extend to a depth of between 25 and 100 % of the thickness of the oxide layer (e.g., between about 2 and 8 µm). .

Although in the foregoing example embodiment semiconductor devices have been illustrated with crack-stop structures that include metal material overlapping the top surface of an oxide material in which they are disposed, in other embodiments the crack stop structures may only line the bottom surface and sidewalls of an opening in the oxide layer, and may either extend vertically above the top surface of the oxide layer without overlapping it, or may not extend vertically above the top surface of the oxide layer (e.g., in some embodiments, the metal material over the top surface of the oxide layer may all be removed by, e.g., a grinding or polishing step).

Although in the foregoing example embodiment semiconductor devices have been illustrated with crack-stop structures formed in openings of an oxide layer (e.g., silicon oxide), in other embodiments similar crack-stop structures may be formed in openings of layers comprising other materials (e.g., nitrides, silicides, carbides, polymers, resins, photoresists, etc.) mutatis mutandis.

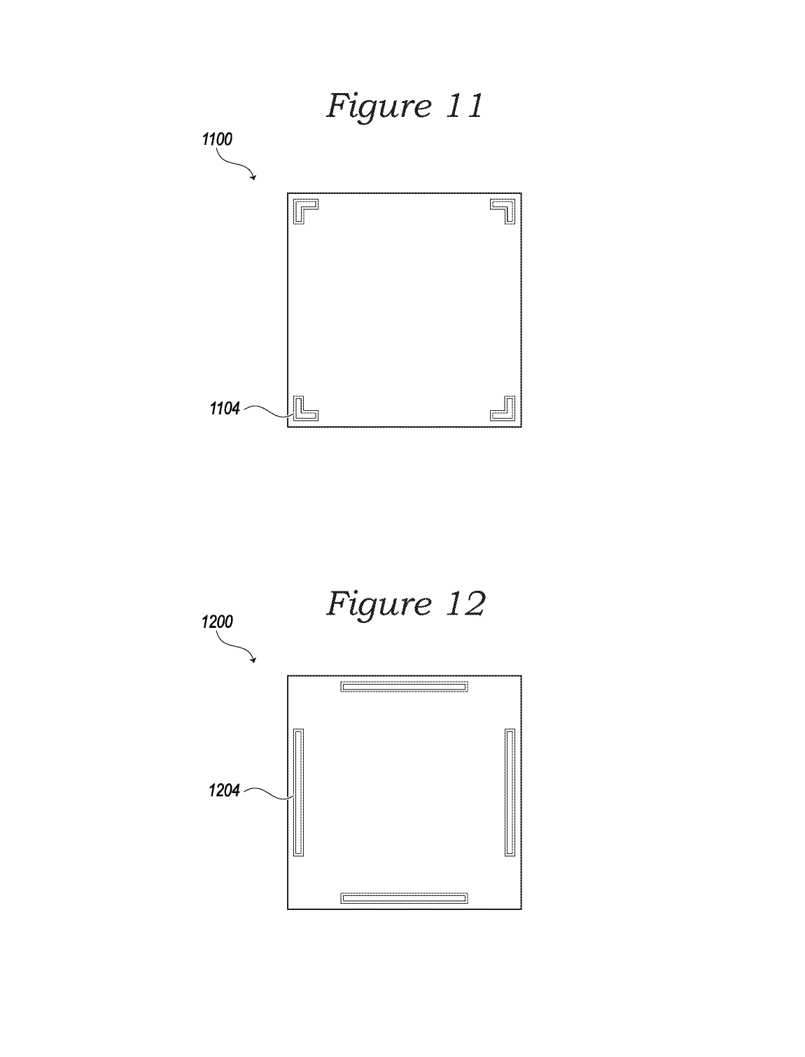

According to one aspect of the present disclosure, the location in which a crack-stop structure is located in the plan view of a semiconductor device may be selected based on regions known to be prone to delamination. For example, FIGS. 11 and 12 are simplified schematic plan views of semiconductor devices with crack-stop structures in accordance with embodiments of the present technology in which crack-stop structures (in the form of elongated trenches) are disposed in corners (FIG. 11) and/or along sidewalls (FIG. 12) of semiconductor devices 1100 and 1200, respectively. The width of the opening in which crack stop structures may be between 1 and 8 µm. and may extend linearly between about 0.5 and 10 µm. The openings may be formed as a straight (or, in other embodiments, curved or zig-zagging) elongated trench (as crack-stop structure 1204) or may follow the shape of the corner (e.g. in an “L” shape, such as crack-stop structure 1104) of a semiconductor device. Although in FIGS. 11 and 12, one crack-stop structure is illustrated in each corner and/or along each sidewall, other embodiments in which multiple discrete crack-stop structures are placed in corners, along sidewalls, or in other locations of the semiconductor device are also contemplated by the instant disclosure.

In accordance with one aspect of the present disclosure, the semiconductor devices illustrated in FIGS. 3 through 11 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

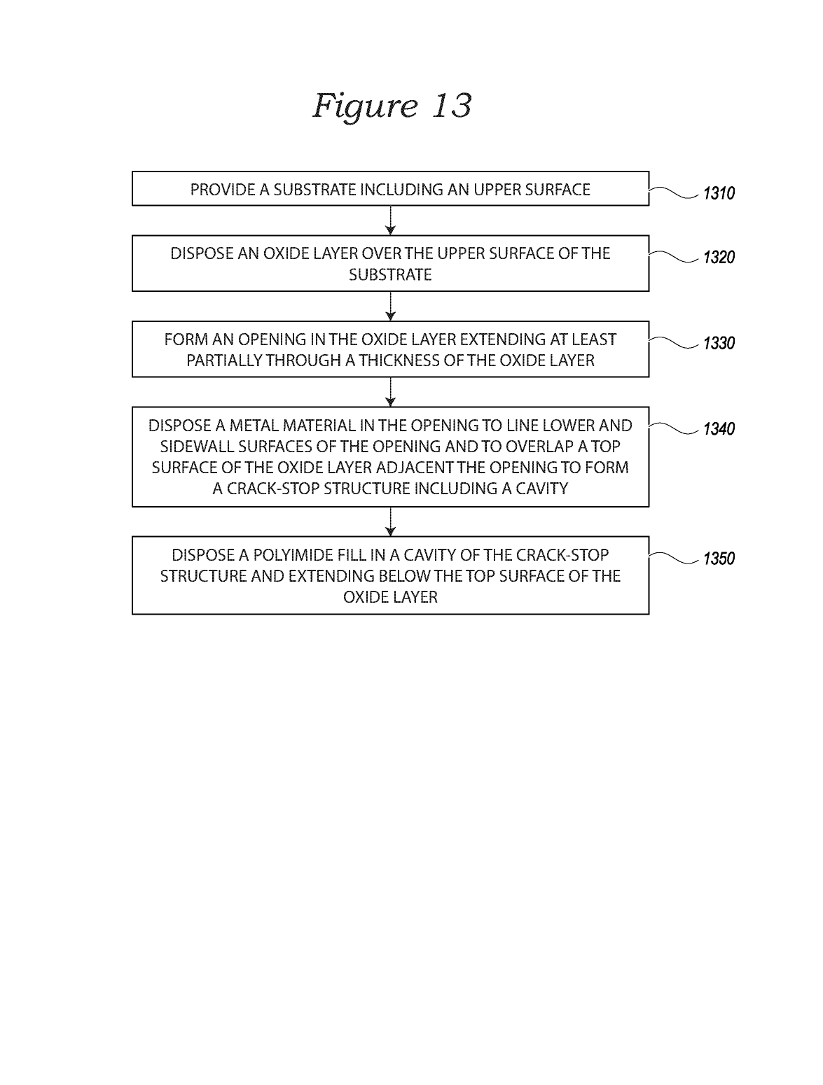

FIG. 13 is a flow chart illustrating a method of making a semiconductor device in accordance with one aspect of the present disclosure. The method includes providing a substrate including an upper surface (box 1310), disposing an oxide layer over the upper surface of the substrate (box 1320), and forming an opening in the oxide layer extending at least partially through a thickness of the oxide layer (box 1330) The method further includes disposing a metal material in the opening to line lower and sidewall surfaces of the opening and to overlap a top surface of the oxide layer adjacent the opening to form a crack-stop structure including a cavity (box 1340) and disposing a polyimide fill in a cavity of the crack-stop structure and extending below the top surface of the oxide layer (box 1350).

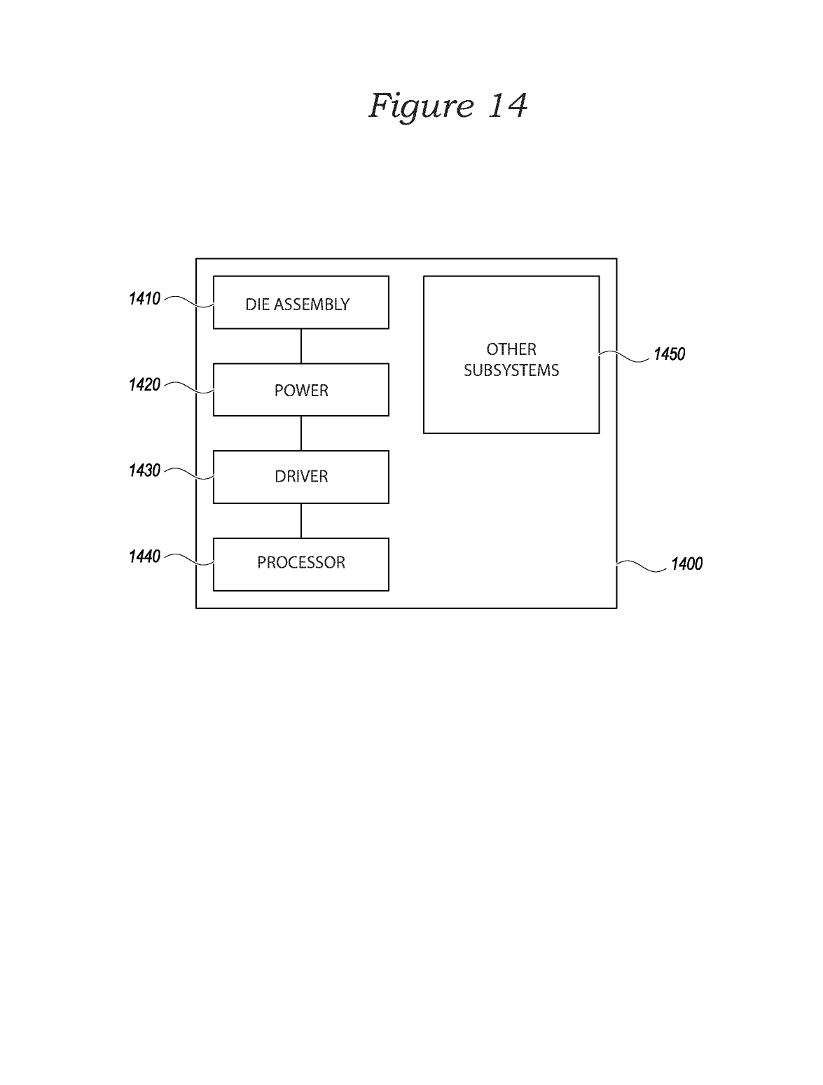

Any one of the semiconductor devices and semiconductor device assemblies described above with reference to FIGS. 3 through 13 can be incorporated into any of a myriad of larger and/or more complex systems, a representative example of which is system 1400 shown schematically in FIG. 14. The system 1400 can include a semiconductor device assembly (e.g., or a discrete semiconductor device) 1402, a power source 1404, a driver 1406, a processor 1408, and/or other subsystems or components 1410. The semiconductor device assembly 1402 can include features generally similar to those of the semiconductor devices described above with reference to FIGS. 2–11. The resulting system 1400 can perform any of a wide variety of functions, such as memory storage, data processing, and/or other suitable functions. Accordingly, representative systems 1400 can include, without limitation, hand-held devices (e.g., mobile phones, tablets, digital readers, and digital audio players), computers, vehicles, appliances and other products. Components of the system 1400 may be housed in a single unit or distributed over multiple, interconnected units (e.g., through a communications network). The components of the system 1400 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In other embodiments, the term “substrate” can refer to a package-level substrate upon which other semiconductor devices are carried, such as a printed circuit board (PCB), an interposer, or another semiconductor device.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device, comprising:
a substrate including an upper surface;
an oxide layer disposed over the upper surface of the substrate;
a crack-stop structure extending into an opening in the oxide layer, the crack-stop structure comprising a metal material that lines lower and sidewall surfaces of the opening and that overlaps a top surface of the oxide layer adjacent the opening; and
a polyimide fill disposed in a cavity of the crack-stop structure and extending below the top surface of the oxide layer.

2. The semiconductor device of claim 1, wherein a portion of the metal material that lines the lower surface of the opening has a thickness less than a thickness of the oxide layer.

3. The semiconductor device of claim 1, wherein the polyimide fill also overlaps the crack-stop structure and is in contact with the top surface of the oxide layer.

4. The semiconductor device of claim 1, wherein the opening in the oxide layer is generally circular in a plan view.

5. The semiconductor device of claim 1, wherein the opening in the oxide layer extends partially, but not completely, through a thickness of the oxide layer.

6. The semiconductor device of claim 1, wherein the opening in the oxide layer extends completely through a thickness of the oxide layer.

7. The semiconductor device of claim 1, wherein the metal material comprises aluminum.

8. A method of making a semiconductor device, comprising:
providing a substrate including an upper surface;
disposing an oxide layer over the upper surface of the substrate;
forming an opening in the oxide layer extending at least partially through a thickness of the oxide layer;
disposing a metal material in the opening to line lower and sidewall surfaces of the opening and to overlap a top surface of the oxide layer adjacent the opening to form a crack-stop structure including a cavity;
disposing a polyimide fill in a cavity of the crack-stop structure and extending below the top surface of the oxide layer.

9. The method of claim 8, wherein a portion of the metal material that lines the lower surface of the opening has a thickness less than the thickness of the oxide layer.

10. The method of claim 8, wherein the polyimide fill also overlaps the crack-stop structure and is in contact with the top surface of the oxide layer.

11. The method of claim 8, wherein the opening in the oxide layer is generally circular in a plan view.

12. The method of claim 8, wherein the opening in the oxide layer extends partially, but not completely, through the thickness of the oxide layer.

13. The method of claim 8, wherein the opening in the oxide layer extends completely through the thickness of the oxide layer.

14. The method of claim 8, wherein the metal material comprises aluminum.

15. A semiconductor device, comprising:
a substrate including an upper surface;
an oxide layer disposed over the upper surface of the substrate;
a crack-stop structure extending into an opening in the oxide layer, the crack-stop structure comprising a metal material that lines lower and sidewall surfaces of the opening and that extends above a top surface of the oxide layer; and
a fill material disposed in a cavity of the crack-stop structure and extending below the top surface of the oxide layer, the fill material having a lower elastic modulus than that of the metal material.

16. The semiconductor device of claim 15, wherein a portion of the metal material that lines the lower surface of the opening has a thickness less than a thickness of the oxide layer.

17. The semiconductor device of claim 15, wherein the fill material also overlaps the crack-stop structure and is in contact with the top surface of the oxide layer.

18. The semiconductor device of claim 15, wherein the opening in the oxide layer extends partially, but not completely, through a thickness of the oxide layer.

19. The semiconductor device of claim 15, wherein the opening in the oxide layer extends completely through a thickness of the oxide layer.

20. The semiconductor device of claim 15, wherein the metal material comprises aluminum.
